(19) United States
(12) Patent Application Publication
(10) Pub. No.: US 2026/0252015 A1
(43) Pub. Date: Aug. 27, 2026

(54) IMAGE FORMING APPARATUS

(71) Applicant: CANON KABUSHIKI KAISHA, Tokyo (JP)

(72) Inventors: KEN OI, Tokyo (JP); DAIGO YAMAUCHI, Kanagawa (JP)

(21) Appl. No.: 19/544,878

(22) Filed: Feb. 19, 2026

(30) Foreign Application Priority Data
Feb. 26, 2025 (JP) 2025-029559

(51) Int. Cl. G03G 15/00; G01R 33/07; G03G 15/01; G03G 21/16

(52) U.S. Cl. CPC G03G 15/556; G01R 33/07; G03G 15/0173; G03G 21/1661

(57) ABSTRACT

An image forming apparatus includes a storage portion configured to house toner and a first magnetic material, a magnetic material unit including a permanent magnet and a second magnetic material, the permanent magnet including a first end surface and a second end surface, the second magnetic material being lower in residual magnetic flux density than the permanent magnet, the magnetic material unit being configured to move inside the storage portion based on an amount of toner in the storage portion, and a sensor configured to output a signal based on a magnetic field formed by the permanent magnet.

### BACKGROUND

### Field of the Technology

The present disclosure relates to an image forming apparatus.

### Description of the Related Art

An image forming apparatus described in Japanese Patent Laid-Open No. 2004-286849 includes a magnet and a detection unit that detects changes in the magnetic field formed by the magnet, detecting the remaining amount of toner.

In a case where a magnetic material exists around a magnet, magnetic force acts between the magnetic material and the magnet, which may decrease detection accuracy of the detection unit.

### SUMMARY

The present disclosure is directed to suppressing decrease in detection accuracy of the detection unit.

According to an aspect of the present disclosure, an image forming apparatus includes a storage portion configured to house toner and a first magnetic material, a magnetic material unit including a permanent magnet and a second magnetic material, the permanent magnet including a first end surface and a second end surface, the second magnetic material being lower in residual magnetic flux density than the permanent magnet, the magnetic material unit being configured to move inside the storage portion based on an amount of toner in the storage portion, and a sensor configured to output a signal based on a magnetic field formed by the permanent magnet, wherein, in a case where a direction from one of magnetic poles to another magnetic pole of the permanent magnet is defined as a first direction, the first end surface is one end of the permanent magnet in the first direction, and the second end surface is another end of the permanent magnet on a side opposite to the one end in the first direction, wherein, in a case where a position of the permanent magnet closest to the sensor is defined as a proximity position, and the permanent magnet is at the proximity position, a shortest distance between the first end surface and the sensor is longer than a shortest distance between the second end surface and the sensor, wherein, in a case where the permanent magnet is at the proximity position, a shortest distance between the first magnetic material and the second magnetic material is smaller than a shortest distance between the first magnetic material and the first end surface, and wherein, as viewed in the first direction, the second magnetic material includes an overlap portion configured to overlap with the first end surface, and a non-overlap portion configured not to overlap with the first end surface.

Features of the present disclosure will become apparent from the following description of embodiments with reference to the attached drawings. The following description of embodiments is described by way of example.

### BRIEF DESCRIPTION OF THE DRAWINGS

FIG. 1 is a schematic diagram of an image forming apparatus according to a first embodiment.

FIG. 2 is a schematic diagram of a developing unit and a toner cartridge according to the first embodiment.

FIG. 3 is a plan view of the image forming apparatus according to the first embodiment.

FIG. 4 is a perspective view of a to-be-detected unit according to the first embodiment.

FIG. 5 is a block diagram illustrating a control unit according to the first embodiment.

FIGS. 6A and 6B are plan views of the image forming apparatus according to the first embodiment.

FIGS. 7A and 7B are each a schematic diagram of a magnetic field formed by a permanent magnet according to the first embodiment.

FIG. 8 is a plan view of the permanent magnet and a yoke member according to the first embodiment.

FIG. 9 is a graph illustrating magnetic flux densities of magnetic fields formed by permanent magnets according to the first embodiment.

FIG. 10 is a schematic diagram of an image forming apparatus according to a second embodiment.

FIGS. 11A and 11B are plan views of the image forming apparatus according to the second embodiment.

FIG. 12 is a schematic diagram of a magnetic field formed by a permanent magnet according to a first modification.

FIG. 13 is a plan view of the permanent magnet and the yoke member according to the first modification.

FIG. 14 is a graph illustrating magnetic flux densities in magnetic fields formed by permanent magnets according to the first modification.

### DESCRIPTION OF THE EMBODIMENTS

### First Embodiment

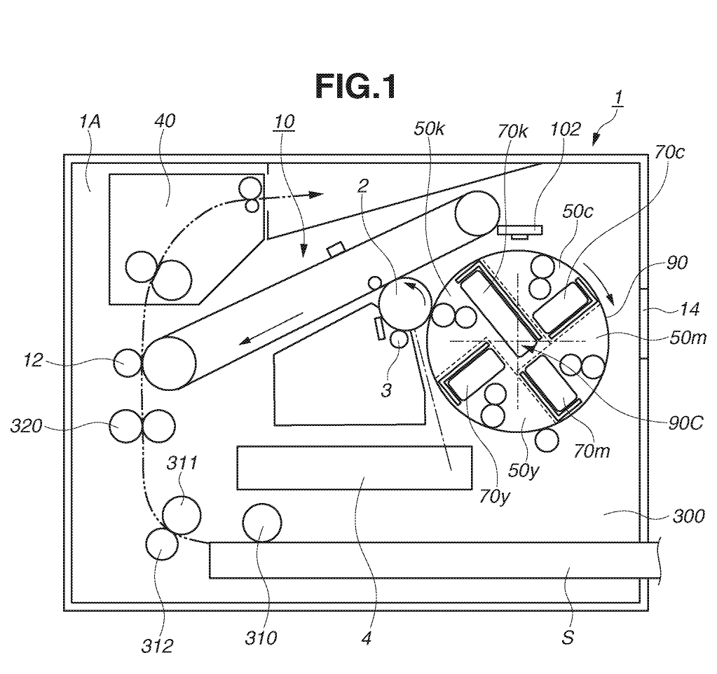

An image forming apparatus 1 according to a first embodiment will now be described with reference to FIGS. 1, 2, 3, 4, 5, 6A and 6B, 7A and 7B, 8, and 9. Letters y, m, c, and k appended to developing units 50y, 50m, 50c, and 50k, and toner cartridges 70y, 70m, 70c, and 70k, and the like, respectively, described below indicate colors of toner. The basic configuration and functions are common between a plurality of members that have the same reference numerals and differ in colors. For example, the toner cartridges 70y, 70m, 70c, and 70k have the same basic configurations and functions. Thus, when it is unnecessary to distinguish between these members, the letters y, m, c, and k are omitted, and one of the members is described. For example, when a toner cartridge 70 is described, the description applies to any of the toner cartridges 70y, 70m, 70c, and 70k.

### Entire Configuration of Image Forming Apparatus

An entire configuration of the image forming apparatus 1 will be described. The image forming apparatus 1 is a laser beam printer that forms images on sheets S using an electrophotographic method. The image forming apparatus 1 is a color laser beam printer including the four developing units 50y, 50m, 50c, and 50k. Examples of a sheet S as a recording material (a recording medium) include paper, such as plain paper and thick paper, a plastic film, cloth, a surface-treated sheet material, such as coated paper, a sheet material having a special shape, such as an envelope and index paper, and other various sheet materials different in size and material.

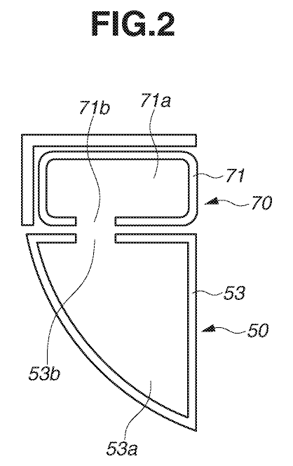

A schematic configuration and image forming operation of the image forming apparatus 1 are described with reference to FIGS. 1 and 2.

FIG. 1 is a schematic diagram illustrating a cross-sectional configuration of the image forming apparatus 1. FIG. 2 is a conceptual diagram illustrating a configuration to replenish toner from the toner cartridge 70 to a developing unit 50. As illustrated in FIG. 1, the image forming apparatus 1 includes an image forming apparatus main body (hereinafter, referred to as an apparatus main body) 1A, and the toner cartridges 70y, 70m, 70c, and 70k attachable to and detachable from the apparatus main body 1A. The apparatus main body 1A in the present embodiment is a portion of the image forming apparatus 1 excluding the toner cartridges 70y, 70m, 70c, and 70k. The apparatus main body 1A of the image forming apparatus 1 includes, as an image carrier that carries an electrostatic latent image, an electrophotographic photosensitive member (hereinafter, referred to as a photosensitive drum) 2 having a drum shape (a cylindrical shape). A charging roller 3 and a scanner 4, serving as an exposure device, are disposed in the vicinity of the photosensitive drum 2.

The charging roller 3 is an example of a charging unit to uniformly charge the photosensitive drum 2. The scanner 4 is an exposure unit that performs exposure by irradiating the photosensitive drum 2 with a laser beam corresponding to image information. By irradiating the charged photosensitive drum 2 with the laser beam, an electrostatic latent image is formed on the surface of the photosensitive drum 2.

The apparatus main body 1A includes a sheet storage portion 300, a pickup roller 310, a feed roller 311, a separation roller 312, a pair of conveyance rollers 320, a secondary transfer roller 12, a fixing device 40, and an intermediate transfer unit 10. The pickup roller 310 is a feeding unit that feeds the sheets S. The feed roller 311 and the separation roller 312 are examples of a separation conveyance unit, which conveys the sheets S while the sheets S are separated one by one using frictional force. The secondary transfer roller 12 is an example of a transfer unit that transfers an image from the intermediate transfer unit to a sheet S. The intermediate transfer unit 10 is an example of an intermediate transfer member that carries the image primarily transferred from the photosensitive drum 2 to secondarily transfer the image to the sheet S.

The apparatus main body 1A further includes a rotary main body (a rotary, a rotation member, or a developing device) 90 including the developing units 50y, 50m, 50c, and 50k. The rotary main body 90 can rotate around a rotation axis (a rotation center) 90C. The toner cartridges 70y, 70m, 70c, and 70k are detachably (removably) mounted to the rotary main body 90. Each of the developing units (first to fourth developing units) 50y, 50m, 50c, and 50k is an example of a developing unit that develops (visualizes) the electrostatic latent image formed on the photosensitive drum 2 into a toner image using a toner of a corresponding color. The developing units 50y, 50m, 50c, and 50k are developing members that develop the electrostatic latent image formed on the photosensitive drum using yellow toner, magenta toner, cyan toner, and black toner, respectively. Specifically, each of the developing members develops the electrostatic latent image formed on the photosensitive drum 2 using a developer (toner) housed in a developing frame member 53.

The toner cartridges 70y, 70m, 70c, and 70k corresponding to the developing units 50y, 50m, 50c, and 50k, respectively, are mounted to the rotary main body 90. The yellow toner, the magenta toner, the cyan toner, and the black toner are housed as the toner to be replenished to the developing units 50y, 50m, 50c, and 50k in the toner cartridges 70y, 70m, 70c, and 70k, respectively. One of the four colors may be referred to as a first toner, one of the remaining three colors may be referred to as a second toner, and one of the remaining two colors may be referred to as a third toner, and the remaining toner may be referred to as a fourth toner. For example, the black toner may be an example of the first toner, and the magenta toner may be an example of the second toner. The numbering is used merely for convenience in description, and can be appropriately interchanged in principle.

A not-illustrated motor M1 causes the rotary main body 90 to rotate around the rotation axis 90C. The rotary main body 90 rotates around the rotation axis 90C to take a developing orientation in which any of the developing rollers 51y, 51m, 51c, and 51k faces the photosensitive drum 2. An orientation in which the developing roller 51y faces the photosensitive drum 2 is referred to as a yellow developing orientation. An orientation in which the developing roller 51m faces the photosensitive drum 2 is referred to as a magenta developing orientation. An orientation in which the developing roller 51c faces the photosensitive drum 2 is referred to as a cyan developing orientation. An orientation in which the developing roller 51k faces the photosensitive drum 2 is referred to as a black developing orientation. In other words, the rotary main body 90 can rotate around the rotation axis 90C so as to change positions of the developing rollers 51y, 51m, 51c, and 51k with respect to the photosensitive drum 2. The black developing orientation is an example of a first developing orientation in which a first developing roller (the developing roller 51k) faces the photosensitive drum 2. Another developing orientation is an example of a second developing orientation in which a second developing roller (any of the developing rollers 51y to 51c) faces the photosensitive drum 2. The yellow, magenta, cyan, and black developing orientations may be referred to as the first to fourth developing orientations. The numbering is used merely for convenience in description, and can be appropriately interchanged in principle.

### Image Forming Operation

An image forming operation according to the present embodiment will now be described. First, the photosensitive drum 2 is rotated in an arrow direction (the counterclockwise direction) illustrated in FIG. 1 in synchronization with the rotation of the intermediate transfer unit 10. Subsequently, the surface of the photosensitive drum 2 is uniformly charged by the charging roller 3. When a full-color image is formed on the sheet S, the rotary main body 90 rotates in an arrow direction (the clockwise direction) illustrated in FIG. 1 while supporting the developing units 50y, 50m, 50c, and 50k as described below. Further, an electrophotographic process is repeatedly performed while the developing rollers 51y, 51m, 51c, and 51k are moved to the developing position one by one.

First, the scanner 4 emits a laser beam based on image data corresponding to a yellow image to form an electrostatic latent image corresponding to the yellow image on the surface of the photosensitive drum 2. In parallel with formation of the electrostatic latent image, the motor M1 causes the rotary main body 90 to rotate and then take the yellow developing orientation. While the rotary main body 90 is taking the yellow developing orientation, the developing roller 51y at the developing position develops the electrostatic latent image formed on the photosensitive drum 2 using the yellow toner.

At the developing position, each of the developing rollers 51y, 51m, 51c, and 51k develops the electrostatic latent image while being in contact with the photosensitive drum 2. A yellow toner image on the photosensitive drum 2 is primarily transferred to the intermediate transfer unit 10. Thereafter, the rotary main body 90 is rotated to move the developing rollers 51m, 51c, and 51k to the developing position in that order, which results in formation of toner images of the respective colors. In other words, after the yellow toner image is formed on the intermediate transfer unit 10, the rotary main body 90 takes the magenta developing orientation, and then a magenta toner image is formed on the intermediate transfer belt 10a. After the magenta toner image is formed on the intermediate transfer belt 10a, the rotary main body 90 takes the cyan developing orientation, and then a cyan toner image is formed on the intermediate transfer belt 10a.

After the cyan toner image is formed on the intermediate transfer belt 10a, the rotary main body 90 takes the black developing orientation, and then a black toner image is formed on the intermediate transfer belt 10a. After the black toner image is formed on the intermediate transfer belt 10a, the rotary main body 90 rotates around the rotation axis 90C in the arrow direction (the clockwise direction) illustrated in FIG. 1, and returns to take the yellow developing orientation. The primary transfer is repeated so that the toner images of the four colors are superimposed on each other on the intermediate transfer belt 10a, which results in formation of a full-color image on the intermediate transfer belt 10a.

On the other hand, the sheets S are fed by the pickup roller 310 from the sheet storage portion 300 disposed on a lower part of the apparatus main body 1A. The sheets S are conveyed to the pair of conveyance rollers 320 while being separated one by one by the feed roller 311 and the separation roller 312. The pair of conveyance rollers 320 conveys the fed sheets S to a transfer portion (a secondary transfer portion) as a nip portion between the intermediate transfer unit 10 and the secondary transfer roller 12. The full-color image on the intermediate transfer belt 10a is transferred (secondarily transferred) to the surface of a conveyed sheet S. The sheet S with the full-color image transferred thereon is conveyed to the fixing device 40. At the fixing device 40, the sheet S is heated and pressed, so that the image is fixed to the sheet S. The sheet S that has passed through the fixing device 40 is discharged as a product to the outside of the image forming apparatus 1. On the other hand, when a monochrome image is formed on the sheet S, the rotary main body 90 takes the black developing orientation. In this state, after the electrostatic latent image is formed on the surface of the photosensitive drum 2 by charging and exposure of the photosensitive drum 2, the electrostatic latent image is developed using the black toner by the developing roller 51k positioned at the developing position. The black toner image is primarily transferred to the intermediate transfer unit 10, and is then secondarily transferred to the sheet S. The subsequent processes are the same as those in the case of the color image.

### Supply of Toner

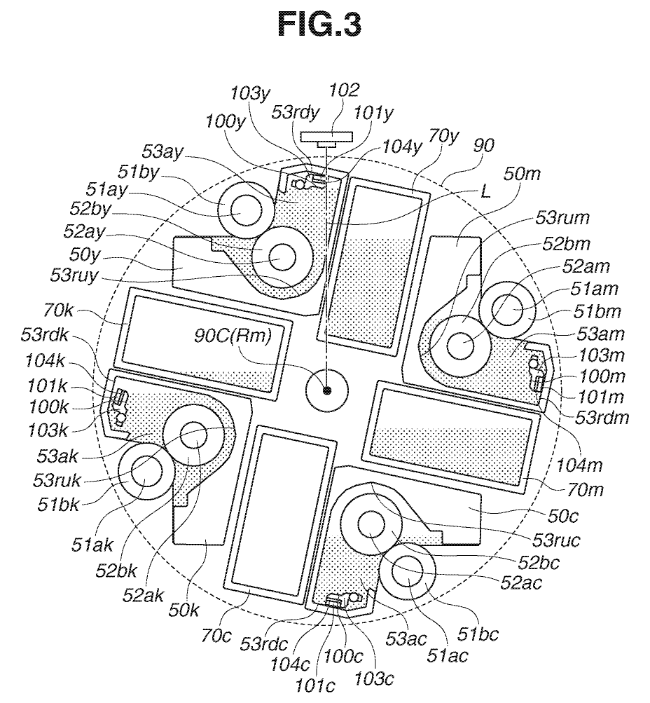

A configuration to supply toner from the toner cartridge 70 to the developing unit 50 will be described with reference to FIGS. 2 and 3. FIG. 3 is a plan view of the image forming apparatus 1. The toner cartridge 70 includes a toner frame member 71. The toner frame member 71 includes a toner storage portion 71a for housing toner, and a discharge opening 71b communicating with the toner storage portion 71a. The developing unit 50 includes a developing frame member (a storage frame member) 53. The developing units 50y, 50m, 50c, and 50k include developing frame members 53y, 53m, 53c, and 53k, respectively. The developing frame member 53 includes a developing-side storage portion (a toner supply chamber) 53a, and a reception opening 53b communicating with the developing-side storage portion 53a. The developing unit 50 includes a developing roller 51 and a supply roller 52, but the developing roller 51 and the supply roller 52 are omitted in FIG. 2.

The discharge opening 71b faces the reception opening 53b, and the toner storage portion 71a and the developing-side storage portion 53a of the developing unit 50 communicate with each other. When the toner is supplied from the toner cartridge 70 to the developing unit 50, at least a part of the reception opening 53b is positioned below at least a part of the discharge opening 71b. In other words, when the rotary main body 90 takes an orientation in which at least a part of the reception opening 53b is positioned below at least a part of the discharge opening 71b, the toner is supplied. The toner housed in the toner storage portion 71a is discharged through the discharge opening 71b, and the toner discharged through the discharge opening 71b is housed in the developing-side storage portion 53a through the reception opening 53b. The toner housed in the developing-side storage portion 53a is supplied to the developing roller 51 by the supply roller 52. In this manner, the toner housed in the toner storage portion 71a is supplied to the developing roller 51.

The developing roller 51 and the supply roller 52 will be described with reference to FIG. 3. The developing-side storage portion 53a houses the developing roller 51 and the supply roller 52. In the present embodiment, only a part of the developing roller 51 is housed in the developing-side storage portion 53a. The developing roller 51 is a developer carrier that rotates while carrying the toner as developer to supply the toner to the photosensitive drum 2. The developing roller 51 includes a shaft 51a, and a rubber layer 51b covering the shaft 51a. By the shaft 51a receiving driving force by a not-illustrated driving mechanism, the developing roller 51 rotates. The shaft 51a contains a magnetic material. In the following description, a magnetic material refers to a material magnetized by being placed in a magnetic field. Examples of the magnetic material include iron, nickel, and cobalt. An alloy containing a magnetic material is also referred to as a magnetic material. For example, stainless steel containing iron is a magnetic material. The supply roller 52, which is a supplying member disposed in contact with the developing roller 51, supplies the toner to the developing roller 51. The supply roller 52 includes a shaft 52a and a foam layer 52b covering the shaft 52a. By the shaft 52a receiving driving force by a not-illustrated driving mechanism, the supply roller 52 rotates. The shaft 52a contains a magnetic material. The developing roller 51 and the supply roller 52 can be each referred to as a magnetic material roller (a rotation member) that rotates inside the developing-side storage portion 53a to supply the toner. Further, in the following description, the shaft 51a or the shaft 52a is referred to as a first magnetic material in some cases.

### Configuration to Detect Remaining Amount in Developing-Side Storage Portion

A configuration to detect the remaining amount of toner in the developing frame member 53 will be described. The amount of toner inside the toner cartridge 70 is reduced every time the image forming operation is performed. With a low amount of toner inside the toner cartridge 70, it is difficult for the toner to be supplied from the toner cartridge 70 to the developing frame member 53. As a result, the remaining amount of toner in the developing-side storage portion 53a is reduced. When image formation is performed with a remaining low amount of toner, an image defect may occur on a printed product. Thus, the image forming apparatus 1 according to the present embodiment includes a component for detecting the remaining amount of toner in the developing frame member 53.

As illustrated in FIG. 3, the developing unit 50 includes a to-be-detected unit 103. In other words, the developing units 50y,50m, 50c, and 50k include to-be-detected units 103y, 103m, 103c, and 103k, respectively. The image forming apparatus 1 also includes a magnetic sensor 102. The to-be-detected unit 103 includes a permanent magnet 101 and a yoke member 104. In other words, the to-be-detected units 103y, 103m, 103c, and 103k include permanent magnets 101y, 101m, 101c, and 101k, respectively. Specifically, the permanent magnet 101 is housed in the developing-side storage portion 53a. The to-be-detected units 103y, 103m, 103c, and 103k include yoke members 104y, 104m, 104c, and 104k, respectively. As illustrated in FIGS. 1 and 3, the magnetic sensor 102 is disposed above the rotary main body 90. The magnetic sensor 102 faces the rotary main body 90. The magnetic sensor 102 is a detection unit that detects a magnetic field formed by the permanent magnet 101.

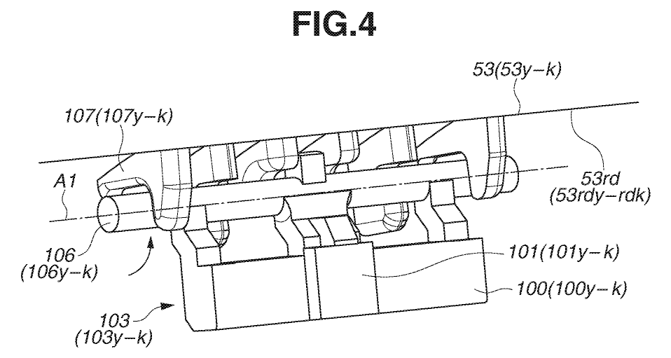

The to-be-detected unit 103 will now be described. FIG. 4 is a perspective view of the to-be-detected unit 103. In FIG. 4, the yoke member 104 is omitted. In the following description, in a rotation radial direction of the rotary main body 90, a direction from a rotation center Rm of the rotary to the outside of the rotary is referred to as a first radial direction. Further, an end part of the developing frame member 53 downstream in the first radial direction is referred to as a storage portion downstream end 53rd, and an end part upstream of the developing frame member 53 is referred to as a storage portion upstream end 53ru. In the first radial direction, the distance between the storage portion upstream end 53ru and the rotary center Rm is shorter than that between the storage portion downstream end 53rd and the rotation center Rm. Further, the storage portion downstream end 53rd and the storage portion upstream end 53ru are opposed to each other in the first radial direction. Further, the storage portion downstream end 53rd and the storage portion upstream end 53ru extend in a direction intersecting the first radial direction. As illustrated in FIG. 3, the shortest distance between the shaft 52a and the rotation center Rm is shorter than the distance between the permanent magnet 101 and the rotation center Rm.

As illustrated in FIG. 4, the to-be-detected unit 103 is supported by the developing frame member 53. Specifically, the to-be-detected unit 103 is supported by the storage portion downstream end 53rd. The developing frame member 53 houses a holding member 107 and the to-be-detected unit 103. In other words, the developing frame member 53 includes the holding member 107 and the to-be-detected unit 103. The to-be-detected unit 103 includes the permanent magnet 101, the yoke member 104, a support member 100, and a rotary shaft 106. In the following description, a unit formed by the permanent magnet 101 and the yoke member 104 is referred to as a magnetic material unit 105. The holding member 107, which is integrated with the developing frame member 53, holds the rotary shaft 106 with respect to the developing frame member 53. The rotary shaft 106 is rotatably held by the holding member 107. In other words, the rotary shaft 106 is a supported portion supported by the developing frame member 53 via the holding member 107.

The support member 100 is integrated with the rotary shaft 106. In other words, the support member 100 is held by the holding member 107. The support member 100 is rotatable around the rotary shaft 106. The rotary shaft 106 extends in a rotation axis direction of the rotary main body 90. As illustrated in FIG. 3, the support member 100 is a support member that supports the yoke member 104. The support member 100 and the yoke member 104 engage with each other by not-illustrated engagement portions. The permanent magnet 101 and the yoke member 104 are bonded with adhesive tape (an adhesive member). With the above-described configuration, the permanent magnet 101 supported by the support member 100 via the yoke member 104 is also rotatable around the rotary shaft 106. In other words, a rotation axis of the permanent magnet 101 extends in the rotation axis direction of the rotary main body 90.

Further, the to-be-detected unit 103 is disposed inside the developing frame member 53 so as to be movable (rotatable) with respect to the developing frame member 53. In other words, the to-be-detected unit 103 is disposed inside the developing frame member 53 so as to be movable (rotatable) with respect to the magnetic sensor 102.

The support member 100 includes a paramagnetic material or a diamagnetic material. A paramagnetic material and a diamagnetic material refer to materials that are not a ferromagnetic material and are weakly magnetized even when placed in an external magnetic field. Further, a paramagnetic material and a diamagnetic material refer to materials that lose magnetism when an external magnetic field is removed. However, a paramagnetic material is magnetized in the same direction as that of an external magnetic field, whereas a diamagnetic material is magnetized in the direction opposite to that of the external magnetic field. Examples of paramagnetic materials include aluminum, platinum, and manganese.

Examples of diamagnetic materials include resin, copper, and lead. The support member 100 contains at least one of the paramagnetic materials or the diamagnetic materials described above. As a result, in detection of the remaining amount of toner described below, the support member 100 can have reduced impact on the magnetic field formed by the permanent magnet 101.

Resin has lower density than that of metal, such as iron or aluminum. Thus, in a case where the support member 100 is made of resin, the support member 100 hardly sinks in the toner inside the developing-side storage portion 53a, so that the to-be-detected unit 103 is likely to be placed on the toner surface. This makes it possible to suppress decrease in accuracy in detecting the remaining amount of toner.

### Determination as to Remaining Amount of Toner in Developing-Side Storage Portion

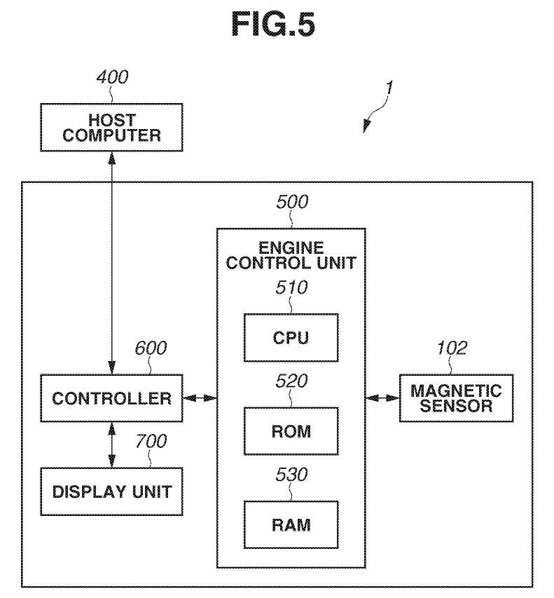

A method will now be described of determining the amount of toner in the developing-side storage portion 53a. First, a configuration of a control unit of the image forming apparatus 1 will be described with reference to FIG. 5. FIG. 5 is a block diagram illustrating the configuration of the control unit of the image forming apparatus 1. The image forming apparatus 1 includes an engine control unit 500, a controller 600, and a display unit 700. A host computer 400 transmits print jobs to the image forming apparatus 1. When a print job is received from the host computer 400, the controller 600 causes the engine control unit 500 to control the image forming operation based on the print job. The display unit 700 is a display device that can display information. The display unit 700 is a display device including a display screen, such as a display. The engine control unit 500 includes a central processing unit (CPU) 510, a read only memory (ROM) 520, and a random access memory (RAM) 530. The ROM 520 is a nonvolatile memory holding and storing control programs and various types of data. For example, the ROM 520 stores determination results of the amount of toner determined using the CPU 510. The RAM 530 is a volatile memory that stores temporary data.

The magnetic sensor 102 outputs a signal to the engine control unit 500 based on a magnetic field formed by the permanent magnet 101. Specifically, the magnetic sensor 102 changes a signal to be output based on the magnitude of a detected magnetic flux density. Thus, the magnetic sensor can also be referred to as a detection unit that detects a magnetic field formed by the permanent magnet 101. The magnetic sensor 102 is a Hall integrated circuit (IC) sensor that linearly outputs output voltages. The magnetic sensor 102 may be a switch sensor whose output is inverted when a magnetic flux passing through a magnetic flux detection unit is greater than or equal to a predetermined threshold.

The rotary main body 90 performs rotation caused by the image forming operation of the image forming apparatus 1, pre-rotation before the image forming operation, and post-rotation after the image forming operation. These rotations cause the developing units 50y, 50m, 50c, and 50k to move closer to the magnetic sensor 102 in that order. During a period when the rotary main body 90 rotates and the developing units 50y, 50m, 50c, and 50k pass in front of the magnetic sensor 102 in that order, the magnetic sensor 102 constantly detects a magnetic field. The magnetic sensor 102 may detect the magnetic field only at a timing when each of the developing units 50y, 50m, 50c, and 50k moves closer to the magnetic sensor 102. The magnetic sensor 102 outputs a signal corresponding to the number of lines of magnetic force (the magnetic flux density) passing through the magnetic sensor 102. The CPU 510 of the image forming apparatus 1 determines the remaining amount of toner in the developing-side storage portion 53a based on the signal output from the magnetic sensor 102.

As the developing-side storage portion 53a moves closer to and farther from the magnetic sensor 102 due to rotation of the rotary main body 90, the to-be-detected unit 103 moves closer to and farther from the magnetic sensor 102. It is desirable for the magnetic sensor 102 to detect the magnetic field of the permanent magnet 101 at a timing when the developing-side storage portion 53a moves closer to the magnetic sensor 102. A line segment L illustrated in FIG. 3 is a virtual line segment connecting the rotation center Rm and the magnetic sensor 102 as viewed in the rotation axis direction of the rotary main body 90. As illustrated in FIG. 3, the magnetic sensor 102 according to the present embodiment detects the magnetic field of the permanent magnet 101y at a timing when the permanent magnet 101y overlaps with the line segment L as viewed in the rotation axis direction of the rotary main body 90. The magnetic sensor 102 also detects the magnetic field of each of the permanent magnets 101m, 101c, and 101k at a similar timing.

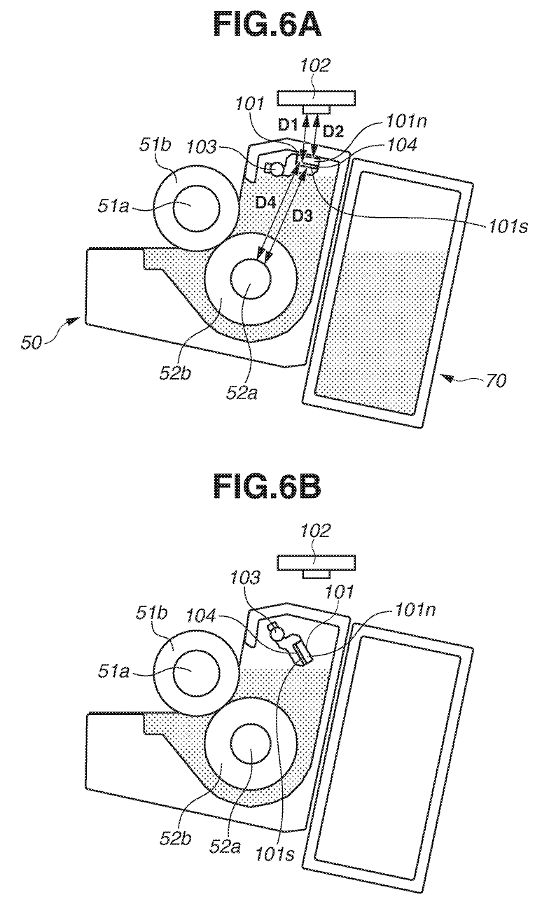

FIG. 6A illustrates a state where the developing-side storage portion 53a is sufficiently filled with the toner. The state illustrated in FIG. 6A is a state at the above-described timing when the permanent magnet 101y overlaps with the line segment L. FIG. 6B illustrates a state where the remaining amount of toner in the developing-side storage portion 53a is less than a predetermined threshold. FIG. 6A and FIG. 6B illustrate the same orientation (rotation phase) of the rotary.

As the remaining amount of toner is reduced, the toner surface in the developing-side storage portion 53a is lowered. The toner surface here indicates the upper surface formed by the toner. A position of the to-be-detected unit 103 supported on the toner surface also changes as the toner surface decreases. Specifically, the to-be-detected unit 103 (the magnetic material unit 105) rotates so as to move away from the magnetic sensor 102. In other words, the to-be-detected unit 103 (the magnetic material unit 105) moves inside the developing-side storage portion 53a based on the amount toner in the developing-side storage portion 53a. As illustrated in FIG. 6B, as a distance between the to-be-detected unit 103 and the magnetic sensor 102 is increased, the magnetic flux density passing through the magnetic sensor 102 is reduced. In other words, the signal output from the magnetic sensor 102 is changed. In a case where the remaining amount of toner in the developing-side storage portion 53a is less than the predetermined threshold, the engine control unit 500 controls the controller 600 to notify the display unit 700 of information about the remaining amount of toner. The controller 600 causes the display unit 700 to display the information about the remaining amount of toner. In other words, the image forming apparatus 1 notifies the information about the remaining amount of toner based on the signal output from the magnetic sensor 102. The information about the remaining amount of toner is, for example, information representing the amount of toner or information representing replacement of a toner cartridge.

As described above, the image forming apparatus 1 detects the remaining amount of toner based on changes in the signal output from the magnetic sensor 102. The orientation of the rotary main body 90 illustrated in FIG. 6A is referred to as a first orientation, and the amount of toner in the developing-side storage portion 53a illustrated in FIG. 6A is referred to as a first amount. The state of the image forming apparatus 1 illustrated in FIG. 6A is referred to as a first state. The amount of toner in the developing-side storage portion 53a illustrated in FIG. 6B is referred to as a second amount. The second amount is lower than the first amount. In FIG. 6B, the rotary main body 90 takes the first orientation. The state of the image forming apparatus 1 illustrated in FIG. 6B is referred to as a second state. A shortest distance between the permanent magnet 101 and the shaft 52a when the image forming apparatus 1 is in the second state is shorter than a shortest distance between the permanent magnet 101 and the shaft 52a when the image forming apparatus 1 is in the first state.

### Configuration of Yoke Member

A configuration will be described of the yoke member. In a case where the magnetic material exists around the permanent magnet 101, magnetic force (attractive force or repulsive force) acts between the magnetic material and the permanent magnet 101 in some cases. In the present embodiment, the shaft 52a of the supply roller 52 and the shaft 51a of the developing roller are each made of a magnetic material. Thus, magnetic force acts between the permanent magnet 101 and the shaft 52a and between the permanent magnet 101 and the shaft 51a in some cases. In this case, the positions of the permanent magnet 101 and the magnetic sensor 102 may be changed due to influence of the shaft 52a and the shaft 51a, decreasing detection accuracy of the magnetic sensor 102. Thus, the image forming apparatus 1 includes the yoke member 104 (a second magnetic material).

The yoke member 104 will be described. The yoke member 104 contains a soft magnetic material. Examples of the soft magnetic material include pure iron (Fe), silicon steel (Si-Fe), Permalloy, Sendust, and Permendur. Examples of the soft magnetic material also include soft ferrite, an amorphous magnetic alloy, and a nanocrystal magnetic alloy. For example, in the present embodiment, a residual magnetic flux density of the yoke member 104 (soft magnetic material) is less than a residual magnetic flux density of the permanent magnet 101. Further, for example, in the present embodiment, the residual magnetic flux density of the yoke member 104 (the soft magnetic material) is greater than a residual magnetic flux density of the support member 100.

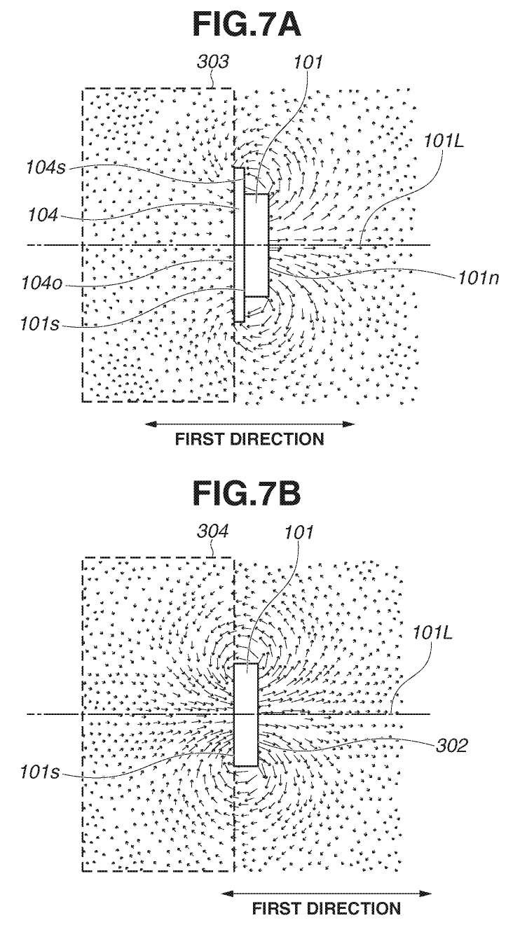

FIGS. 7A and 7B are schematic diagrams each illustrating a magnetic field formed by the permanent magnet 101. FIG. 7A illustrates a case where the image forming apparatus 1 includes the yoke member 104. In contrast, FIG. 7B illustrates a case where the image forming apparatus 1 does not include the yoke member 104. The permanent magnet 101 includes an S-pole surface 101s including the S pole, and an N-pole surface 101n including the N pole. Hereinafter, a direction from one of the magnetic poles to the other magnetic pole of the permanent magnet 101 is referred to as a first direction. In other words, the first direction includes a direction from the S-pole surface 101s to the N-pole surface 101n and a direction from the N-pole surface 101n to the S-pole surface 101s. The S-pole surface 101s is referred to as a first end surface that is one end of the permanent magnet 101 in the first direction. In a case where the S-pole surface 101s is referred to as the first end surface, the N-pole surface 101n can be referred to as a second end surface that is the other end of the permanent magnet 101 on the side opposite to the one end in the first direction. Further, the S-pole surface 101s may be referred to as the second end surface, and the N-pole surface 101n may be referred to as the first end surface. Lines of magnetic force emanating from the N-pole surface 101n enter the S-pole surface 101s. Further, when the lines of magnetic force emanating from the N-pole surface 101n pass through the magnetic sensor 102, the magnetic sensor 102 detects the magnetic field. In the present embodiment, the permanent magnet 101 is a neodymium magnet, but may be another permanent magnet.

An arrangement of the permanent magnet 101 and the yoke member 104 will be described. In the following description, a position of the permanent magnet 101 closest to the magnetic sensor 102 is referred to as a proximity position. The proximity position refers to a position where a shortest distance between the permanent magnet 101 and the magnetic sensor 102 becomes the smallest of the positions where the permanent magnet 101 can be disposed. For example, the permanent magnets 101 illustrated in FIGS. 3 and 6A are at the proximity position. As illustrated in FIG. 6A, a shortest distance between the first end surface (the S-pole surface 101s) and the magnetic sensor 102 with the permanent magnet 101 being at the proximity position is denoted by D1. A shortest distance between the second end surface (the N-pole surface 101n) and the magnetic sensor 102 with the permanent magnet 101 being at the proximity position is denoted by D2. The shortest distance D1 is greater than the shortest distance D2. A distance between the shaft 52a (the first magnetic material) and the yoke member 104 (the second magnetic material) with the permanent magnet 101 being at the proximity position is denoted by D3. Further, a shortest distance between the shaft 52a (the first magnetic material) and the first end surface (the S-pole surface 101s) with the permanent magnet 101 being at the proximity position is denoted by D4. The distance D3 is less than the shortest distance D4. While the example is described where the distance D3 is less than the shortest distance D4 when the first magnetic material is the shaft 52a, this also holds true for the shaft 51a.

As illustrated in FIG. 6A, with the permanent magnet 101 being at the proximity position, the shaft 52a, the yoke member 104, the S-pole surface 101s, the N-pole surface 101n, and the magnetic sensor 102 are arranged in that order in the direction from the S-pole surface 101s to the N-pole surface 101n. Likewise, in the direction from the S-pole surface 101s to the N-pole surface 101n, the shaft 51a, the yoke member 104, the S-pole surface 101s, the N-pole surface 101n, and the magnetic sensor 102 are arranged in that order.

As illustrated in FIG. 7A, in the first direction, a length of the permanent magnet 101 is longer than a length of the yoke member 104. Further, as illustrated in FIG. 7A, in the direction orthogonal to the first direction, the length of the yoke member 104 is less than or equal to two times the length of the permanent magnet 101. By setting the size of the yoke member 104 in the above-described manner, the magnetic material unit 105 can be downsized.

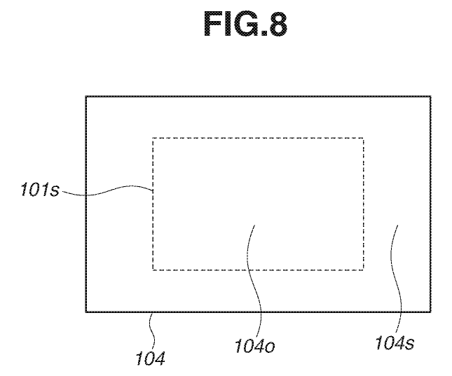

FIG. 8 is a plan view of the permanent magnet 101 and the yoke member 104 as viewed in the direction (the first direction) from the S-pole surface 101s to the N-pole surface 101n. An area surrounded by solid lines indicates an area of the yoke member 104, and an area surrounded by dashed lines indicates an area of the S-pole surface 101s of the permanent magnet 101. As viewed in the first direction, the yoke member 104 (the second magnetic material) includes an overlap portion 104o that overlaps with the first end surface (the S-pole surface 101s). Further, as viewed in the first direction, the yoke member 104 includes a non-overlap portion 104s that does not overlap with the first end surface.

As viewed in the first direction, the non-overlap portion 104s surrounds the overlap portion 104o.

In other words, as viewed in the first direction, the overlap portion 104o and the permanent magnet 101 are disposed inside the outer edge of the yoke member 104.

The yoke member 104 is attracted to the S-pole surface 101s by magnetic force acting between the yoke member 104 and the permanent magnet 101. Further, as described above, the yoke member 104 and the S-pole surface 101s of the permanent magnet 101 are bonded with adhesive tape. The adhesive tape is used in addition to the magnetic force acting between the yoke member 104 and the permanent magnet 101, which makes it possible to prevent positional deviation of the permanent magnet 101 and the yoke member 104.

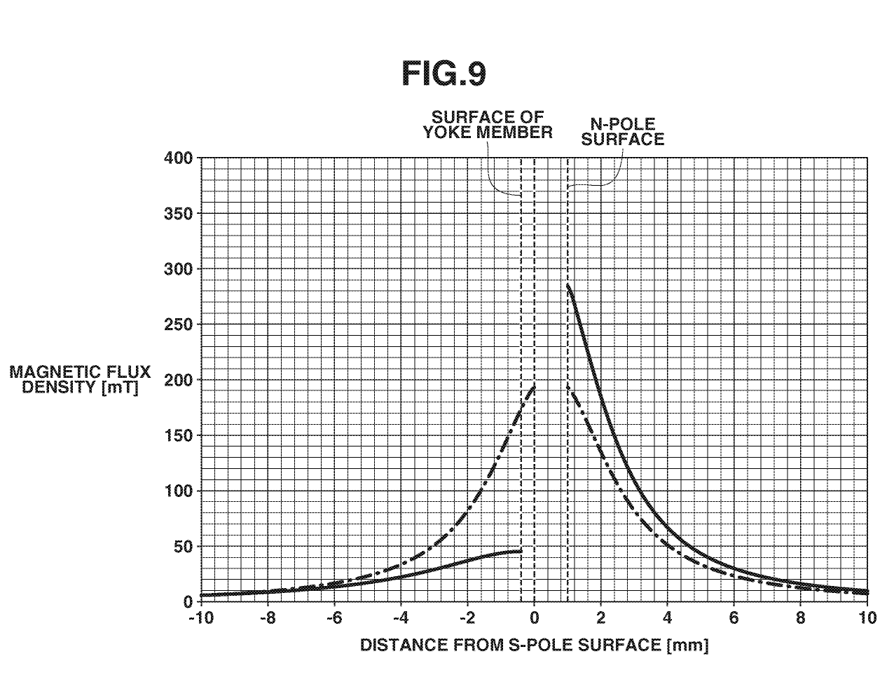

The effect of providing the yoke member 104 will now be described with reference to FIGS. 7A and 7B, and FIG. 9. FIG. 9 is a graph illustrating magnetic flux densities of magnetic fields formed by the permanent magnet 101. A virtual line 101L each illustrated in FIGS. 7A and 7B passes through the center of the S-pole surface 101s and extends in the first direction. The magnetic flux densities illustrated in FIG. 9 each show a magnetic flux density on the virtual line 101L. A horizontal axis represents distances from the S-pole surface 101s to the N-pole surface 101n in the direction from the S-pole surface 101s. A vertical axis represents magnitudes of the magnetic flux densities. A solid line indicates the case where the yoke member 104 is provided (FIG. 7A). A dashed-dotted line indicates the case where the yoke member 104 is not provided (FIG. 7B).

An area 303 and an area 304 respectively illustrated in FIG. 7A and FIG. 7B indicate magnetic flux distributions on the S-pole side of the permanent magnet 101. It can be understood from comparison between the area 303 and the area 304 that the magnetic flux in the area 303 on the S-pole side is lower than in the area 304. Further, as illustrated in the graph in FIG. 9, it can be understood that the magnetic flux densities on the S-pole surface side with the yoke member provided are lower than with the yoke member not provided. This is because the yoke member 104 includes the non-overlap portion 104s as described above. As illustrated in FIGS. 7A and 7B, the lines of magnetic force emanating from the N-pole surface 101n curve around behind the S-pole surface 101s to enter the S-pole surface 101s. In the case where the yoke member 104 includes the non-overlap portion 104s, a part of the lines of magnetic force emanating from the N-pole surface 101n enters the non-overlap portion 104s, and thus does not curve around behind the S-pole surface 101s. On the other hand, as illustrated in FIGS. 6A and 6B, the distance between the shaft 52a and the S-pole surface 101s is shorter than the distance between the shaft 52a and the N-pole surface 101n. Further, the distance between the shaft 51a and the S-pole surface 101s is shorter than the distance between the shaft 51a and the N-pole surface 101n. In other words, the shaft 51a and the 52a are affected by the magnetic flux on the S-pole surface side because of being disposed on the S-pole surface 101s side. Thus, with the yoke member 104 provided, the magnetic flux density on the S-pole surface side is low, and the magnetic force acting between the magnetic material unit 105 and the shaft 51a is reduced. Likewise, the magnetic force acting between the magnetic material unit 105 and the shaft 52a is reduced.

It can be understood from the graph in FIG. 9 that the magnetic flux densities on the N-pole surface 101n side with the yoke member 104 provided are greater than with the yoke member 104 not provided. This is also because the yoke member 104 includes the non-overlap portion 104s. As illustrated in FIG. 7A, in the case where the yoke member 104 includes the non-overlap portion 104s, the lines of magnetic force emanating from the N-pole surface 101n enter the non-overlap portion 104s. Thus, inclinations of the lines of magnetic force after the lines of magnetic force emanate the N-pole surface 101n until the lines of magnetic force return to the S-pole surface 101s become gradual. Due to this change in the inclinations of the lines of magnetic force, the number of lines of magnetic force passing through the magnetic sensor 102 increases, improving the detectability of the magnetic field formed by the permanent magnet 101.

Thus, even in a case where the remaining amount of toner in the developing-side storage portion 53a decreases, the distance between the magnetic sensor 102 and the permanent magnet 101 increases, the magnetic sensor 102 is capable of detecting the magnetic field.

As described above, the image forming apparatus 1 includes the yoke member 104, so that the magnetic force acting between the magnetic material and the permanent magnet 101 can be reduced, suppressing decrease in detection accuracy of the detection unit.

### Second Embodiment

A second embodiment will now be described. In the first embodiment, the rotary image forming apparatus 1 is described as an example. However, the present disclosure can be applied to an image forming apparatus different from a rotary image forming apparatus. As an example, a direct-transfer monochrome image forming apparatus 200 will be described.

Members of the image forming apparatus 200 denoted by the same reference numerals as those of the image forming apparatus 1 according to the first embodiment have the same functions as those described in the first embodiment, and thus, description of the members will be omitted. However, arrangement and dimensions of these members are appropriately changed so as to function in the image forming apparatus 200.

For example, while the image forming apparatus 200 includes a photosensitive drum 2 as with the image forming apparatus 1, the image forming apparatus 200 is configured so that transfer is directly performed on a recording medium between the photosensitive drum 2 and a transfer roller 9 facing the photosensitive drum 2.

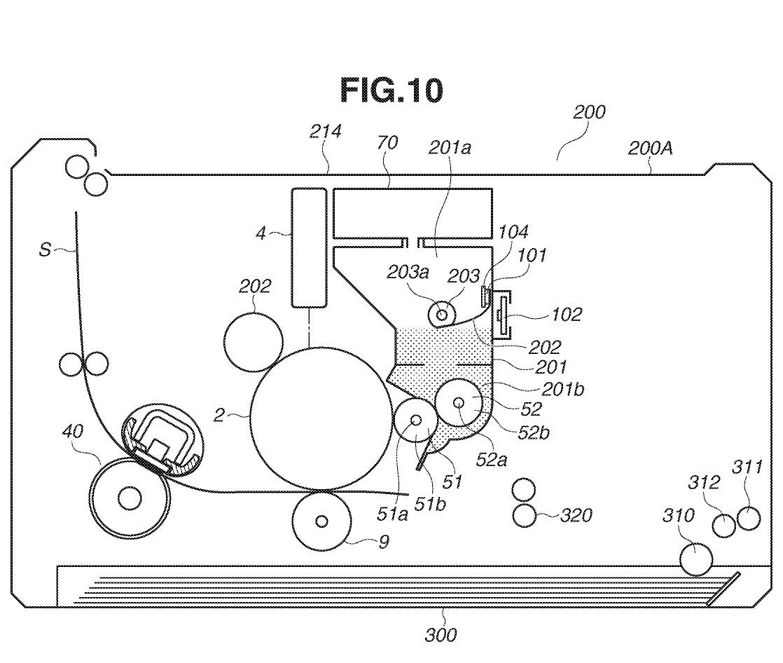

Differences between the image forming apparatus 1 and the image forming apparatus 200 will now be described with reference to FIG. 10. FIG. 10 is a schematic diagram of the image forming apparatus 200. In the image forming apparatus 200, a toner cartridge 70 that houses black toner is attachable to and detachable from an apparatus main body 200A of the image forming apparatus 200. Further, the image forming apparatus 200 includes a toner storage portion 201. When the toner is supplied from the toner cartridge 70 to the toner storage portion 201, the toner storage portion 201 houses the toner. The toner storage portion 201 includes a magnet storage portion 201a and a developing roller storage portion 201b. The magnet storage portion 201a and the developing roller storage portion 201b communicate with each other. The toner supplied from the toner cartridge 70 flows to the magnet storage portion 201a, and then flows from the magnet storage portion 201a to the developing roller storage portion 201b. The magnet storage portion 201a includes a to-be-detected unit 204 described below. The developing roller storage portion 201b includes the developing roller 51 and the supply roller 52. The developing roller storage portion 201b houses a part of the developing roller 51.

Further, the image forming apparatus 200 includes the magnetic sensor 102. The magnetic sensor 102 is attached so as to be fixed to the magnet storage portion 201a.

The to-be-detected unit 204 will be described. The to-be-detected unit 204 includes a rotation member 203, a support member 202, a permanent magnet 101, and a yoke member 104. As described in the first embodiment, the unit formed by the permanent magnet 101 and the yoke member 104 is referred to as a magnetic material unit 105. The rotation member 203 is included in the magnet storage portion 201a. The rotation member 203 includes a shaft 203a (a first magnetic material) as a magnetic material. The shaft 203a is rotated by receiving driving force from a not-illustrated driving mechanism. The rotation member 203 is rotated together with the shaft 203a. One end of the flexible support member 202 is fixed to the rotation member 203, and the other end is fixed to the magnetic material unit 105. The support member 202 is rotated with rotation of the rotation member 203 to agitate the toner inside the magnet storage portion 201a. In other words, the rotation member 203 is rotated inside the magnet storage portion 201a to supply the toner. As the magnetic material unit 105 is rotated by rotation of the support member 202, a position of the permanent magnet 101 with respect to the magnetic sensor 102 changes.

A positional relationship of the permanent magnet 101 and the yoke member 104 is the same as that in the first embodiment. In other words, the yoke member 104 is bonded to an S-pole surface 101s. Further, the lines of magnetic force emanating from the N-pole surface 101n pass through the magnetic sensor 102.

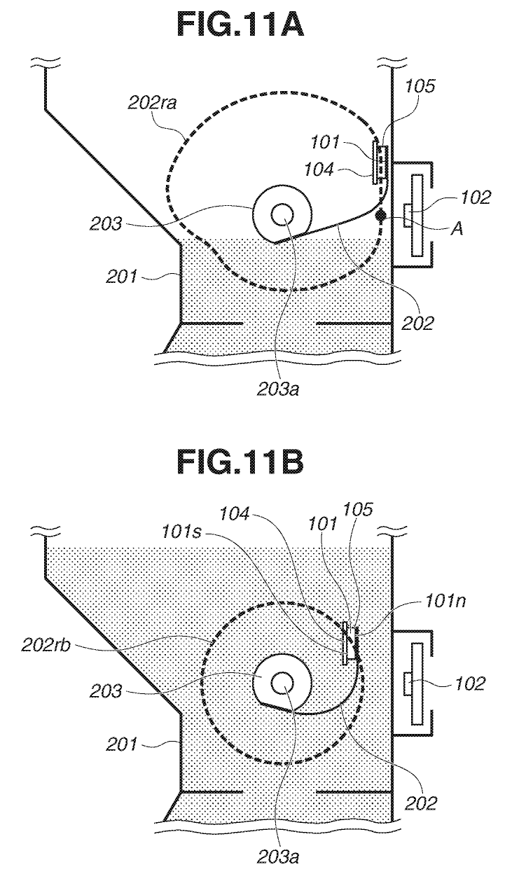

A method of detecting the remaining amount of toner according to the second embodiment will be described with reference to FIGS. 11A and 11B. FIG. 11A illustrates a case where the remaining amount of toner in the magnet storage portion 201a is low, and FIG. 11B illustrates a case where the remaining amount of toner in the magnet storage portion 201a is higher than that of toner illustrated in FIG. 11A. FIGS. 11A and 11B are diagrams as viewed in an axial direction of the rotation member 203. A trajectory 202rb illustrated in FIG. 11B represents a trajectory drawn by the center of the S-pole surface 101s when the magnetic material unit 105 rotates. A trajectory 202ra illustrated in FIG. 11A represents a trajectory drawn by the center of the S-pole surface 101s when the magnetic material unit 105 rotates. The magnetic material unit 105 is rotated with rotation of the rotation member 203. In other words, the magnetic material unit 105 moves so as to approach and move away from the magnetic sensor 102. A point A illustrated in FIG. 11A indicates the proximity position of the permanent magnet 101.

The magnetic sensor 102 detects the magnetic field at a timing when the magnetic material unit 105 is in proximity to the magnetic sensor 102. The support member 202 has flexibility. Thus, when an amount of toner inside the magnet storage portion 201a is sufficient, the permanent magnet 101 rotates to draw the trajectory 202rb. In contrast, when the amount of toner inside the magnet storage portion 201a is low, the permanent magnet 101 rotates to draw the trajectory 202ra. In other words, the rotation trajectory of the permanent magnet 101 is changed based on the amount of toner inside the magnet storage portion 201a. Specifically, the radius of a rotation when the support member 202 moves in a space with a large amount of toner is shorter than when the support member 202 moves in a space with a low amount of toner. As a result, the magnetic field detected by the magnetic sensor 102 is also changed, allowing the remaining amount of toner to be detected.

The effect of the yoke member 104 in the present embodiment will now be described. In a case where the permanent magnet 101 is in proximity to the magnetic sensor 102 (FIG. 11B), the shaft 203a, the yoke member 104, the S-pole surface 101s, the N-pole surface 101n, and the sensor 102 are arranged in that order in the direction from the S-pole surface 101s to the N-pole surface 101n. As described in the first embodiment, the yoke member 104 is disposed on the S-pole surface 101s side, which makes it possible to reduce the magnetic flux distribution on the S-pole side of the permanent magnet 101. Thus, as compared with the case where the yoke member 104 is not provided, the magnetic force acting between the magnetic material unit 105 and the shaft 203a can be weakened.

As described above, even in the image forming apparatus other than a rotary image forming apparatus, the yoke member 104 that is provided makes it possible to reduce the magnetic force acting between the magnetic material and the permanent magnet 101, suppressing decrease in detection accuracy of the detection unit.

### First Modification

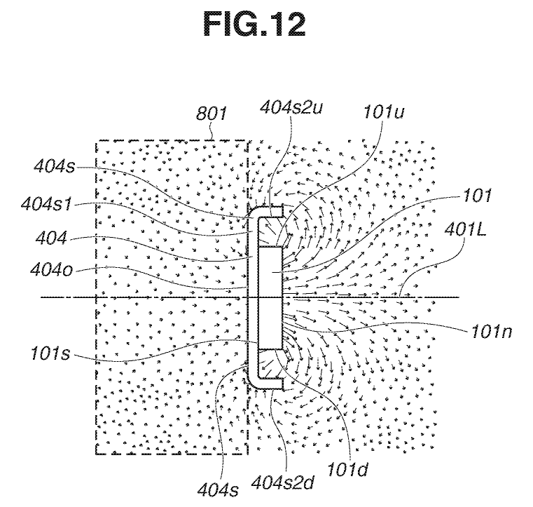

A first modification will now be described. The geometry of the yoke member 104 in the first embodiment and the second embodiment can be replaced with a geometry of a yoke member 404 described in the first modification. FIG. 12 is a cross-sectional view illustrating the yoke member 404. The yoke member 404 includes an overlap portion 404o and a non-overlap portion 404s. The overlap portion 404o is the same as the overlap portion 104o described in the first embodiment. Consequently, a positional relationship of the overlap portion 404o with respect to the permanent magnet 101 is as described in the embodiment, and thus description thereof will be omitted. The non-overlap portion 404s includes an extending portion 404s1 and a bent portion 404s2. The extending portion 404s1 extends from the overlap portion 404o in an extending direction of the S-pole surface 101s. The bent portion 404s2 extends from the non-overlap portion 404s in the direction from the S-pole surface 101s to the N-pole surface 101n. In other words, the bent portion 404s2 extends from the first end surface toward the second end surface.

The permanent magnet 101 includes a first side surface 101u between the S-pole surface 101s and the N-pole surface 101n in the direction (the first direction) from the S-pole surface 101s to the N-pole surface 101n. Further, the permanent magnet 101 includes a second side surface 101d between the S-pole surface 101s and the N-pole surface 101n in the direction from the S-pole surface 101s to the N-pole surface 101n. The first side surface 101u and the second side surface 101d are surfaces opposed to each other. The first side surface 101u and the second side surface 101d extend in the direction from the S-pole surface 101s to the N-pole surface 101n. The bent portion 404s2 includes a first bent portion 404s2u and a second bent portion 404s2d. The first bent portion 404s2u faces the first side surface 101u, and the second bent portion 404s2d faces the second side surface 101d.

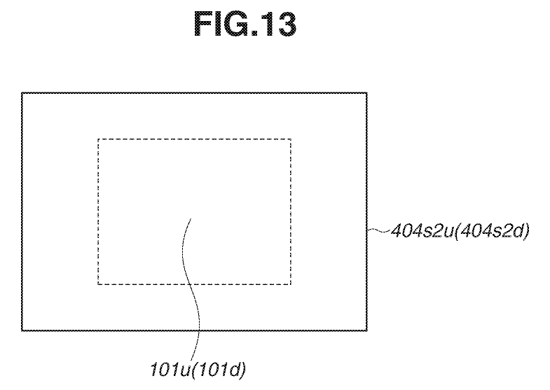

FIG. 13 is a plan view of the permanent magnet 101 and the yoke member 404. FIG. 13 is also a diagram as viewed in a normal direction of the first side surface 101u. An area surrounded by dashed lines illustrated in FIG. 13 is an area of both the first side surface 101u and the second side surface 101d. An area surrounded by solid lines indicates an area of both the first bent portion 404s2u and the second bent portion 404s2d. As viewed in the normal direction of the first side surface 101u, the first bent portion 404s2u overlaps with the first side surface 101u. Further, as viewed in a direction orthogonal to the first direction, the first bent portion 404s2u as a part of the yoke member 404 overlaps with the first side surface 101u. As viewed in the normal direction of the first side surface 101u, the second bent portion 404s2d overlaps with the second side surface 101d. In a case where either the first side surface 101u or the second side surface 101d is referred to as a third end surface, the yoke member 404 (the second magnetic material) overlaps with the third end surface as viewed in a normal direction of the third end surface.

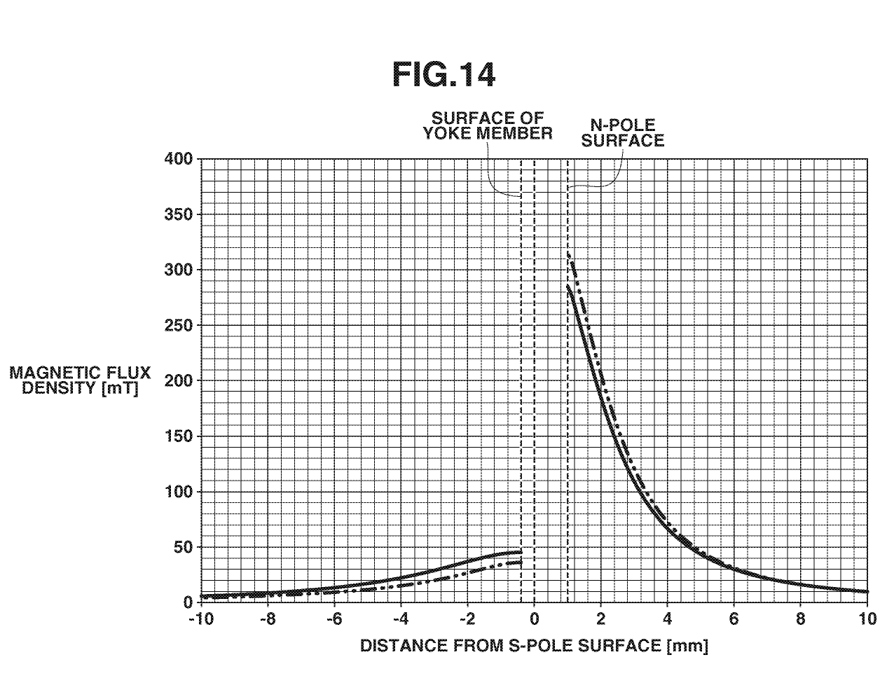

The effect of the yoke member 404 will now be described with reference to FIG. 14. FIG. 14 is a graph illustrating magnetic flux densities of magnetic fields formed by the permanent magnet 101. A virtual line 401L illustrated in FIG. 12 passes through the center of the S-pole surface 101s and extends in the first direction. The magnetic flux densities illustrated in FIG. 14 show magnetic flux densities on the virtual line 401L. A horizontal axis represents distances from the S-pole surface 101s to the N-pole surface 101n in the direction from the S-pole surface 101s. A vertical axis represents magnitudes of the magnetic flux densities. A solid line indicates the case where the yoke member 104 is provided (FIG. 7A) described in the first embodiment. A dashed double-dotted line indicates the case where the yoke member 404 is provided (FIG. 12). It can be understood from the graph in FIG. 14 that the magnetic flux densities on the S-pole surface side with the yoke member 404 provided are lower than with the yoke member 104 provided. Further, it can be understood that the magnetic flux densities on the N-pole surface side with the yoke member 404 provided are higher than with the yoke member 104 provided.

This is because the yoke member 404 includes the bent portion 404s2. The bent portion 404s2 extends from the S-pole surface 101s so as to approach the N-pole surface 101n. Consequently, the lines of magnetic force emanating from the N-pole surface 101n enter the bent portion 404s2, and thus, as compared with the case where the yoke member 104 is provided, the number of lines of magnetic force that curve around behind the S-pole surface 101s is reduced. Further, since the lines of magnetic force emanating from the N-pole surface 101n enter the bent portion 404s2, inclinations of the lines of magnetic force that enter the bent portion 404s2 become gradual as compared with the case where the yoke member 104 is provided. As a result, the number of lines of magnetic force passing through the magnetic sensor 102 is increased, improving the detectability of the magnetic field formed by the permanent magnet 101.

The first embodiment, the second embodiment, and the first modification have been described above. In the first embodiment, the second embodiment, and the first modification, the yoke member 104 or 404 is bonded to the S-pole surface 101s of the permanent magnet 101. However, the polarities of the permanent magnet 101 may be reversed. In other words, the yoke member 104 or 404 may be bonded to the N-pole surface 101n of the permanent magnet 101. In this case, the lines of magnetic force that returns to the S-pole surface 101s passing through the magnetic sensor 102 causes the magnetic sensor 102 to detect the magnetic field.

In addition, the shafts are described as a member on which the magnetic force acts between the permanent magnet 101 and the member. However, even in a case where a magnetic material other than a shaft is provided in the image forming apparatus, the present disclosure can be applied and the effects can be achieved.

According to the embodiments described above, detection accuracy of the detection unit can be prevented from decreasing.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-029559, filed February 26, 2025, which is hereby incorporated by reference herein in its entirety.

What is claimed is:

1. An image forming apparatus comprising:
a storage portion configured to house toner and a first magnetic material;
a magnetic material unit including a permanent magnet and a second magnetic material, the permanent magnet including a first end surface and a second end surface, the second magnetic material being lower in residual magnetic flux density than the permanent magnet, the magnetic material unit being configured to move inside the storage portion based on an amount of toner in the storage portion; and
a sensor configured to output a signal based on a magnetic field formed by the permanent magnet,
wherein, in a case where a direction from one of magnetic poles to another magnetic pole of the permanent magnet is defined as a first direction, the first end surface is one end of the permanent magnet in the first direction, and the second end surface is another end of the permanent magnet on a side opposite to the one end in the first direction,
wherein, in a case where a position of the permanent magnet closest to the sensor is defined as a proximity position, and the permanent magnet is at the proximity position, a shortest distance between the first end surface and the sensor is longer than a shortest distance between the second end surface and the sensor,
wherein, in a case where the permanent magnet is at the proximity position, a shortest distance between the first magnetic material and the second magnetic material is smaller than a shortest distance between the first magnetic material and the first end surface, and
wherein, as viewed in the first direction, the second magnetic material includes an overlap portion configured to overlap with the first end surface, and a non-overlap portion configured not to overlap with the first end surface.

2. The image forming apparatus according to claim 1, further comprising a rotation member configured to rotate inside the storage portion,
wherein the first magnetic material is a shaft provided in the rotation member.

3. The image forming apparatus according to claim 2, further comprising a developing roller configured to supply the toner to a photosensitive drum,
wherein the rotation member is the developing roller.

4. The image forming apparatus according to claim 2, further comprising:
a developing roller configured to supply the toner to a photosensitive drum; and
a supply roller configured to supply the toner to the developing roller,
wherein the rotation member is the supply roller.

5. The image forming apparatus according to claim 1,
wherein the permanent magnet includes a third end surface between the first end surface and the second end surface in the first direction, and
wherein a part of the second magnetic material overlaps with the third end surface as viewed in a direction orthogonal to the first direction.

6. The image forming apparatus according to claim 2, further comprising a rotary including the storage portion,
wherein the magnetic material unit moves with respect to the storage portion as the rotary is rotated.

7. The image forming apparatus according to claim 6, wherein a shortest distance between the rotation member and a rotation center of the rotary is shorter than a shortest distance between the permanent magnet and the rotation center of the rotary.

8. The image forming apparatus according to claim 6, wherein in a case where an orientation of the rotary is defined as a first orientation with the permanent magnet being at the proximity position, a state where the rotary is at the first orientation and an amount of toner in the storage portion is a first amount is defined as a first state, and a state where the rotary is at the first orientation and the amount of toner in the storage portion is a second amount lower than the first amount is defined as a second state, a shortest distance between the permanent magnet and the shaft in the second state is shorter than a shortest distance between the permanent magnet and the shaft in the first state.

9. The image forming apparatus according to claim 1,
wherein a toner cartridge configured to house the toner is attachable and detachable, and
wherein the toner is supplied from the toner cartridge to the storage portion.

10. The image forming apparatus according to claim 1, wherein the sensor changes the signal to be output based on a magnitude of a detected magnetic flux density.

11. The image forming apparatus according to claim 1, wherein information about a remaining amount of toner is notified based on the signal.

12. The image forming apparatus according to claim 1, wherein the permanent magnet and the second magnetic material are bonded with an adhesive member.

13. The image forming apparatus according to claim 1,
wherein the magnetic material unit further includes a support member configured to support the second magnetic material, and
wherein the support member contains resin.
